(19) United States
(12) Patent Application Publication
(10) Pub. No.: US 2026/0145952 A1
(43) Pub. Date: May 28, 2026

(54) ANODE ACTIVE MATERIAL, SOLID-STATE BATTERY, AND METHOD FOR MANUFACTURING ANODE ACTIVE MATERIAL

(71) Applicant: TOYOTA JIDOSHA KABUSHIKI KAISHA, Toyota-shi (JP)

(72) Inventors: Satoshi WAKASUGI, Susono-shi (JP); Masafumi Nose, Mishima-shi (JP)

(73) Assignee: TOYOTA JIDOSHA KABUSHIKI KAISHA, Toyota-shi (JP)

(21) Appl. No.: 19/369,276

(22) Filed: Oct. 26, 2025

(30) Foreign Application Priority Data
Nov. 28, 2024 (JP) 2024-207743

(51) Int. Cl. C01B 33/023; C23C 14/08

(52) U.S. Cl. CPC C01B 33/023; C23C 14/081; C01P 2002/72; C01P 2004/84; C01P 2006/40

(57) ABSTRACT

An anode active material includes a plurality of Si-based particles. The Si-based particles include a porous Si particle and a metal oxide film that is present on at least a part of the surface of the porous Si particle. The metal oxide film contains at least one of an Mg element and an Al element.

### CROSS-REFERENCE TO RELATED APPLICATION

This application claims priority to Japanese Patent Application No. 2024-207743 filed on Nov. 28, 2024. The disclosure of the above-identified application, including the specification, drawings, and claims, is incorporated by reference herein in its entirety.

### BACKGROUND

### 1. Technical Field

The present disclosure relates to anode active materials, solid-state batteries, and methods for manufacturing an anode active material.

### 2. Description of Related Art

Si-based active materials are known to have a high theoretical capacity and are effective in increasing the energy density of batteries. On the other hand, it is also known that Si-based active materials tend to expand during charging.

Japanese Unexamined Patent Application Publication No. 2023-167083 (JP 2023-167083 A) discloses an active material (hereinafter also referred to as “porous Si particle”). The porous Si particle contains Si and has specific voids (hereinafter also referred to as “pores”) inside the primary particle.

### SUMMARY

Since porous Si particles have low strength, the pores of the porous Si particles are prone to collapse. In other words, the pore volume of porous Si particles tends to decrease. When an anode active material layer of a solid-state battery contains porous Si particles with collapsed pores, it may be difficult to reduce expansion and contraction of the anode active material layer during charging or discharging.

The present disclosure has been made in view of the above circumstances.

An object of one embodiment of the present disclosure is to provide an anode active material that is less likely to undergo a decrease in pore volume, and a solid-state battery. An object of another embodiment of the present disclosure is to provide a method for manufacturing an anode active material that is capable of manufacturing an anode active material that is less likely to undergo a decrease in pore volume.

A means for addressing the above issue includes the following aspects.

(1) An anode active material includes a plurality of Si-based particles.

The Si-based particles include a porous Si particle and a metal oxide film that is present on at least a part of a surface of the porous Si particle.

The metal oxide film contains at least one of an Mg element and an Al element.

(2) In the anode active material according to (1), the metal oxide film is made of MgO.

(3) In the anode active material according to (1) or (2), the metal oxide film has a thickness of 3 nm to 8 nm.

(4) A solid-state battery includes a cathode, an anode, and a solid electrolyte layer disposed between the cathode and the anode.

The anode includes the anode active material according to (1).

(5) A method for manufacturing an anode active material includes:
preparing a plurality of porous Si particles; and
depositing a metal silicide onto the porous Si particles by physical vapor deposition in a non-oxidizing atmosphere to form a metal oxide film on at least a part of a surface of the porous Si particles.

The metal silicide contains at least one of an Mg element and an Al element.

One embodiment of the present disclosure provides an anode active material that is less likely to undergo a decrease in pore volume, and a solid-state battery. Another embodiment of the present disclosure provides a method for manufacturing an anode active material that is capable of manufacturing an anode active material that is less likely to undergo a decrease in pore volume.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a cross-sectional view of a porous Si particle according to an embodiment of the present disclosure;

FIG. 2 is a cross-sectional view of an Si-based particle according to an embodiment of the present disclosure;

FIG. 3 is a cross-sectional view of a solid-state battery according to an embodiment of the present disclosure; and

FIG. 4 is a graph showing the X-ray diffraction (XRD) pattern of Si-based particles of Example 1.

### DETAILED DESCRIPTION OF EMBODIMENTS

In the present disclosure, a numerical range expressed using “to” refers to a range inclusive of the values before and after “to” as the minimum and maximum value, respectively. In the present disclosure, a combination of two or more preferred forms is considered a more preferred form.

### (1) Anode Active Material

An anode active material of the present disclosure includes a plurality of Si-based particles. The Si-based particles include a porous Si particle and a metal oxide film that is present on at least a part of the surface of the porous Si particle. The metal oxide film contains at least one of an Mg element and an Al element.

The term “porous Si particle” refers to an Si particle having a plurality of pores. The term “Si particle” refers to a particle containing an Si element as a main component. More specifically, the proportion of the Si element relative to all elements contained in the Si particle may be, for example, 50 mol % or more, 70 mol % or more, or 90 mol % or more. The Si particle may contain elements other than the Si element (e.g., an Li element, an Sn element, an Fe element, a Co element, an Ni element, a Ti element, a Cr element, a B element, and a P element). The Si particle may contain impurities (such as oxides). The elemental Si contained in the Si particle may be amorphous Si or crystalline Si. The crystalline phase contained in the Si particle is not particularly limited.

The anode active material of the present disclosure is less likely to undergo a decrease in pore volume due to the above-described configuration.

This effect is presumed to be due to, but not limited to, the following reasons.

In the present disclosure, the Si-based particles include a metal oxide film. Therefore, the strength of the Si-based particles is higher than that of Si-based particles that do not include a metal oxide film. As a result, it is presumed that the pore volume of the anode active material of the present disclosure is less likely to decrease due to pressing etc. during the production of an electrode assembly of a solid-state battery.

The anode active material of the present disclosure includes a plurality of Si-based particles. The anode active material of the present disclosure may include a plurality of Si-based particles, or may include particles other than the Si-based particles.

The Si-based particle has a plurality of pores. The pore volume of the Si-based particle is not particularly limited, and may be from 0.10 cc/g to 1.00 cc/g, from 0.70 cc/g to 0.90 cc/g, or from 0.75 cc/g to 0.83 cc/g. The method for measuring the pore volume of the Si-based particle is the same as that described in Examples.

The percentage change in pellet thickness of the Si-based particles is higher than 70%, and may be from 75% to 100%, or from 80% to 90%. The higher the percentage change in pellet thickness (%), the less likely the pore volume of the Si-based particle is to decrease due to pressing etc. during the production of an electrode assembly of a solid-state battery. The method for measuring the percentage change in pellet thickness is the same as that described in the Examples.

The particle size (D₅₀) of the Si-based particles may be from 10 μm to 1000 μm, from 20 μm to 100 μm, or from 20 μm to 50 μm. The “particle size (D₅₀)” refers to the particle size (median particle size) at 50% of the volume-based cumulative particle size distribution as measured by a laser diffraction and scattering method.

The metal oxide film is present on at least a part of the surface of the porous Si particle. From the standpoint of increasing the strength of the Si-based particles, it is preferable that the metal oxide film be present over the entire surface of the porous Si particle.

The thickness of the metal oxide film is not particularly limited, and may be from 1 nm to 100 nm. It is preferable that the thickness of the metal oxide film be from 3 nm to 8 nm. With this configuration, the anode active material of the present disclosure is less likely to undergo a decrease in pore volume, and can improve the battery performance of a solid-state battery. From the standpoint of further reducing the likelihood of a decrease in pore volume, the thickness of the metal oxide film may be from 5 nm to 8 nm.

The metal oxide film contains at least one of an Mg element and an Al element, and preferably contains an Mg element. The metal oxide film is preferably made of MgO. With the metal oxide being made of MgO, the anode active material of the present disclosure is less likely to undergo a decrease in pore volume.

The amount of metal (i.e., at least one of an Mg element and an Al element) relative to the Si-based particles is not particularly limited, and may be from 1 mass % to 50 mass %, from 10 mass % to 40 mass %, or from 20 mass % to 30 mass %. The method for measuring the amount of metal relative to the Si-based particles is the same as that described in the Examples.

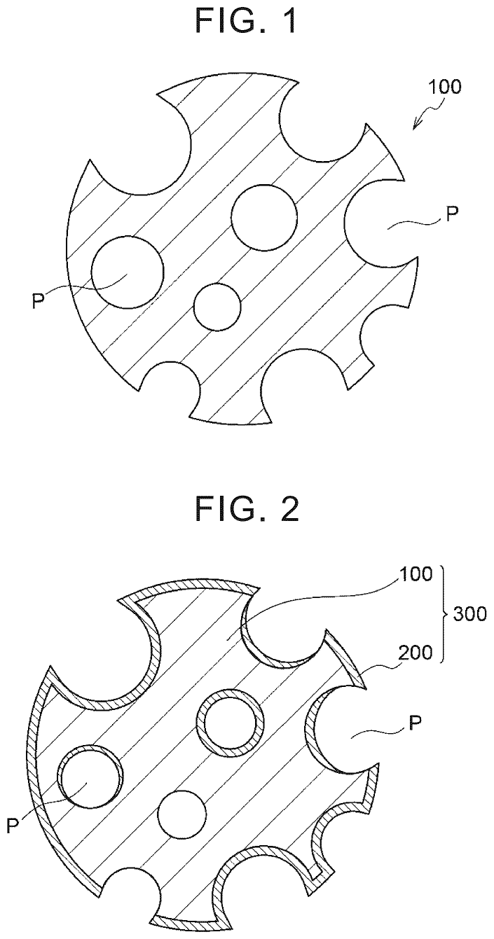

Hereinafter, an example of the porous Si particle of the present disclosure and an example of the Si-based particle of the present disclosure will be described with reference to FIGS. 1 and 2. As shown in FIG. 1, a porous Si particle 100 according to an embodiment of the present disclosure has a plurality of pores P. As shown in FIG. 2, an Si-based particle 300 according to an embodiment of the present disclosure includes the porous Si particle 100 and a metal oxide film 200. The metal oxide film 200 is formed on a part of the surface of the porous Si particle 100. The metal oxide film 200 contains at least one of an Mg element and an Al element.

### (2) Solid-State Battery

A solid-state battery of the present disclosure includes a cathode, an anode, and a solid electrolyte layer disposed between the cathode and the anode. The anode includes an anode active material layer. The anode active material layer contains the anode active material of the present disclosure.

Since the solid-state battery of the present disclosure has the above-described configuration, the anode active material layer expands and contracts due to charging or discharging. Accordingly, even when charging and discharging are alternately repeated, the battery performance of the solid-state battery of the present disclosure is unlikely to deteriorate.

The solid-state battery of the present disclosure may have at least one power generating unit. The power generation unit includes an anode, a solid electrolyte layer, and a cathode. When the solid-state battery includes a plurality of power generation units, the power generation units may be connected in parallel or in series.

### 2.1 Anode

The anode of the present disclosure may include an anode current collector and an anode active material layer formed on at least one of the main surfaces of the anode current collector. The anode active material layer contains the anode active material of the present disclosure, and may further contain at least one of a solid electrolyte, an electrically conductive material, and a binder, as needed.

The solid electrolyte is, for example, a sulfide solid electrolyte, an oxide solid electrolyte, a nitride solid electrolyte, or a halide solid electrolyte. The sulfide solid electrolyte may contain an Li element and an S element. The sulfide solid electrolyte preferably contains at least one of a P element, a Ge element, an Sn element, and an Si element. The sulfide solid electrolyte may contain at least one of an O element and a halogen element (e.g., an F element, a Cl element, a Br element, and an I element). Examples of the sulfide solid electrolyte contained in the solid electrolyte layer include Li₂S—P₂S₅, Li₂S—P₂S₅—ZₘSₙ (where m and n are positive numbers, and Z is one of Ge, Zn, or Ga), and Li₂S—SiS₂-LiₓMO_{y} (where x and y are positive numbers, and M is one of P, Si, Ge, B, Al, Ga, or In). The notation “Li₂S—P₂S₅” refers to a material obtained using a raw material composition containing Li₂S and P₂S₅, and the same applies to other notations. The solid electrolyte may be a known solid electrolyte. The solid electrolyte may be a glass, a glass ceramic, or a crystalline material. The glass can be obtained by amorphizing a raw material composition (e.g., a mixture of Li₂S and P₂S₅). Examples of the amorphization include mechanical milling. The glass ceramic can be obtained by thermally treating glass. The crystalline material can be obtained, for example, by subjecting a raw material composition to a solid-phase reaction. The content of the solid electrolyte in the anode active material layer may be from 20 mass % to 80 mass %.

Examples of the electrically conductive material include a carbon material, metal particles, and an electrically conductive polymer. Examples of the carbon material include acetylene black (AB), Ketjen black (KB), carbon fibers, carbon nanotubes (CNTs), and carbon nanofibers (VGCFs). The volume fraction of the carbon material in the anode active material layer may be from 5 vol % to 10 vol %.

Examples of the binder include fluoride-based binders (such as polyvinylidene fluoride (PVDF)), polyimide-based binders, and rubber-based binders. The volume fraction of the binder in the anode active material layer may be from 2 vol % to 5 vol %.

The anode current collector is a layer that collects current from the anode active material layer. Examples of the material for the anode current collector include aluminum, steel use stainless (SUS), copper, nickel, and carbon. Examples of the form of the anode current collector include a foil.

### 2.2 Solid Electrolyte Layer

The solid electrolyte layer contains a solid electrolyte, and may further contain a binder as needed. The thickness of the solid electrolyte layer may be from 0.1 μm to 300 μm.

Examples of the solid electrolyte include the same substances as those exemplified as the solid electrolyte that may be contained in the anode active material layer. The content of the solid electrolyte in the solid electrolyte layer may be from 70 mass % to 100 mass %, or from 90 mass % to 100 mass %. Examples of the binder include the same substances as those exemplified as the binder that may be contained in the anode active material layer.

### 2.3 Cathode

The cathode includes a cathode active material. The cathode may include a cathode current collector and a cathode active material layer formed on at least one of the main surfaces of the cathode current collector. The cathode active material layer contains the cathode active material, and may further contain at least one of a solid electrolyte, an electrically conductive material, and a binder, as needed.

Examples of the cathode active material include an oxide active material. Examples of the oxide active material include layered rock-salt active materials (e.g., LiNi_{1/3}Co_{1/3}Mn_{1/3}O₂ and LiCoO₂), spinel active materials (e.g., LiMn₂O₄ and Li₄Ti₅O₁₂), and olivine active materials (e.g., LiFePO₄ and LiMnPO₄).

Examples of the solid electrolyte include the same substances as those exemplified as the solid electrolyte that may be contained in the anode active material layer. The content of the solid electrolyte in the cathode active material layer is not particularly limited, and may be from 20 mass % to 80 mass %. Examples of the electrically conductive material include the same substances as those exemplified as the electrically conductive material that may be contained in the anode active material layer. The volume fraction of the electrically conductive material in the cathode active material layer may be from 5 vol % to 10 vol %. Examples of the binder include the same substances as those exemplified as the binder that may be contained in the anode active material layer. The volume fraction of the binder in the cathode active material layer may be from 5 vol % to 10 vol %.

The cathode current collector is a layer that collects current from the cathode active material layer. Examples of the material for the cathode current collector include SUS, aluminum, nickel, iron, titanium, and carbon. Examples of the form of the cathode current collector include a foil.

### 2.4 Casing

The solid-state battery of the present disclosure typically includes a casing. The casing houses the cathode, the solid electrolyte layer, and the anode. The casing is not particularly limited, and may be, for example, a laminated casing.

### 2.5 Embodiment

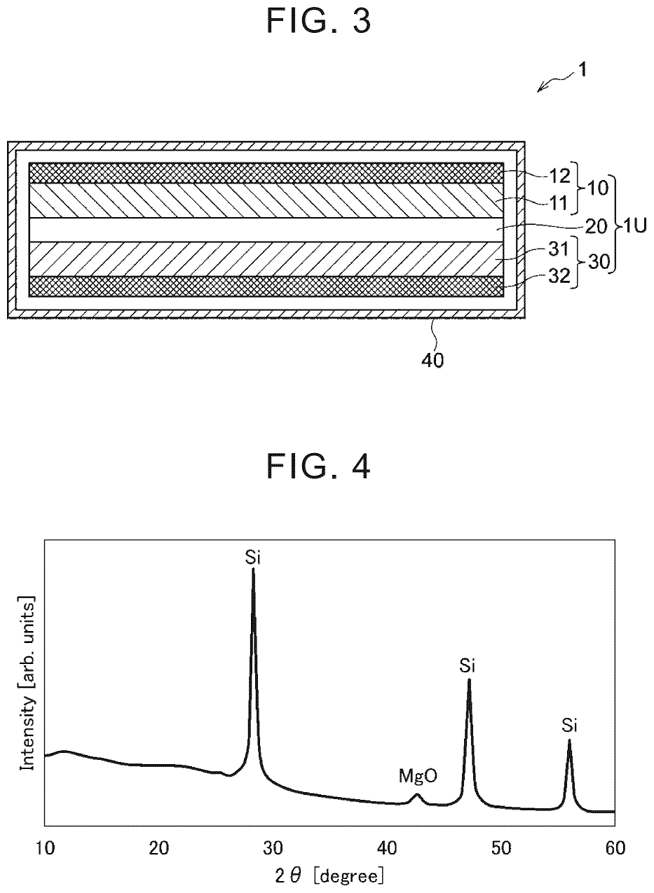

Hereinafter, an example of a battery of the present disclosure will be described with reference to FIG. 3. A battery 1 according to an embodiment of the present disclosure includes one power generation unit 1U and a casing 40. The power generation unit 1U includes an anode 10, a solid electrolyte layer 20, and a cathode 30 laminated in this order. The anode 10 includes an anode active material layer 11 and an anode current collector 12. The cathode 30 includes a cathode active material layer 31 and a cathode current collector 32. The casing 40 houses the power generation unit 1U. The anode active material layer 11 contains the anode active material of the present disclosure.

### 3. Method for Manufacturing Anode Active Material

A method for manufacturing an anode active material according to the present disclosure includes: preparing a plurality of porous Si particles (hereinafter also referred to as “preparation step”); and depositing a metal silicide onto the porous Si particles by physical vapor deposition in a non-oxidizing atmosphere to form a metal oxide film on at least a part of the surface of the porous Si particles (hereinafter also referred to as “coating step”). The metal silicide contains at least one of an Mg element and an Al element. The preparation step and the coating step are performed in this order.

### 3.1 Preparation Step

In the preparation step, a plurality of porous Si particles is prepared. The method for preparing the porous Si particles may be a known method. A method for producing porous Si particles may include, for example, firing Si particles (material: SiOₓ (0<X≤2)) and an Mg source (e.g., Mg₂Si) in a non-oxidizing atmosphere to cause the vaporized Mg source to adhere to the surfaces of the Si particles, and then dissolving magnesium oxide of the Si particles with the Mg source adhering thereto in an acid (e.g., hydrochloric acid or nitric acid) to produce the porous Si particles. In this method, the porous Si particles are considered to be formed by the reaction represented by the following Formula (a):

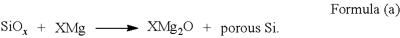

The raw Si particles may have a spherical shape. The term “spherical shape” refers to a condition in which, when the length of the major axis of a primary particle (porous Si particle) is defined as a, and the length of the minor axis of the primary particle is defined as b, the ratio of b to a (b/a) is 0.9 to 1.0. The values of a and b are determined by measuring a cross-sectional image of the porous Si particle.

### 3.2 Coating Step

In the coating step, a metal silicide is deposited onto the porous Si particles by physical vapor deposition in a non-oxidizing atmosphere (e.g., an atmosphere of 10 Pa or less) to form a metal oxide film on at least a part of the surface of the porous Si particles. Si-based particles are thus obtained.

The metal silicide contains at least one of an Mg element and an Al element, and is selected according to the type of metal oxide film. Examples of the metal silicide include magnesium silicide (Mg₂Si), aluminum silicide (Al—Si), and aluminum silicide nitride (AlSiN). The charge ratio of the metal silicide to the porous Si particles may be from 100 mass % to 1000 mass %, or from 200 mass % to 300 mass %.

Examples of the physical vapor deposition include vacuum evaporation, ion plating, sputtering, and pulsed laser deposition (PLD). The physical vapor deposition may be vacuum evaporation. When the physical vapor deposition is vacuum evaporation, the thickness of the metal oxide film and the amount of metal relative to the Si-based particles can be adjusted by controlling the firing temperature of the metal silicide and the porous Si particles (hereinafter also simply referred to as the “firing temperature”). The firing temperature may be any temperature at which the metal silicide vaporizes and the porous Si particles do not melt. The firing temperature may be from 600° C. to 750° C., from 650° C. to 750° C., or from 700° C. to 750° C. When the firing temperature is 700° C. to 750° C., a plurality of Si-based particles is obtained in which the amount of metal relative to the Si-based particles is from 20 mass % to 30 mass % and the thickness of the metal oxide film is from 5 nm to 8 nm.

The present disclosure will be described in more detail below with reference to examples. However, the present disclosure is not limited to these examples.

### 1. EXAMPLES AND COMPARATIVE EXAMPLES

### 1.1 Example 1

### 1.1.1 Preparation Step

Silicon dioxide (composition: SiO₂, particle size: 25 μm, manufacturer: Kojundo Chemical Lab. Co., Ltd.) and magnesium silicide (composition: Mg₂Si, manufacturer: Kojundo Chemical Lab. Co., Ltd.) were prepared. Thereafter, 1.0 part by mass of the silicon dioxide was placed in the upper part of a firing container, and 2.6 parts by mass of the magnesium silicide were placed in the lower part of the firing container. The two materials were separated using a mesh (mesh size: 500 mesh, material: SUS304). The firing container was then placed in a vacuum firing furnace. The silicon dioxide and the magnesium silicide were fired in an atmosphere of 10 Pa or less at 700° C. for six hours. A porous Si precursor was thus obtained. The porous Si precursor was placed in hydrochloric acid (concentration: 1 mol/L) and stirred for one hour. Subsequently, solid and liquid components were separated by suction filtration. The separated solid was washed with ethanol. Porous Si particles were thus obtained.

### 1.1.2 Coating Step

Magnesium silicide (composition: Mg₂Si, manufacturer: Kojundo Chemical Lab. Co., Ltd.) was prepared. Thereafter, 1.0 part by mass of the porous Si particles was placed in the upper part of a firing container, and 2.6 parts by mass of the magnesium silicide were placed in the lower part of the firing container. The two materials were separated using a mesh (mesh size: 500 mesh, material: SUS304). The firing container was then placed in a vacuum firing furnace. The porous Si particles and the magnesium silicide were fired in an atmosphere of 10 Pa or less at 750° C. for two hours. Si-based particles (anode active material) were thus obtained.

### 1.2 Example 2

Si-based particles (anode active material) were obtained in the same manner as in Example 1 except that the firing temperature in the coating step was changed to 650° C.

### 1.3 Comparative Example 1

Porous Si particles (hereinafter, also referred to as “Si-based particles”) (anode active material) were obtained in the same manner as in Example 1 except that the coating step was not performed.

### 2. MEASUREMENT METHOD

### 2.1 X-ray Crystal Structure Analysis

The XRD pattern of the Si-based particles was measured using an X-ray diffractometer. The XRD pattern of the Si-based particles of Example 1 is shown in FIG. 4. It was found that the Si-based particles of Examples 1 and 2 contain an MgO phase (i.e., a metal oxide film). It was also found that the Si-based particles of Comparative Example 1 do not contain an MgO phase (i.e., a metal oxide film).

2.2 Mg Content (mass %)

The amount of Mg (mass %) in the Si-based particles was measured using inductively coupled plasma atomic emission spectrometry (ICP-AES).

### 2.3 Thickness of Metal Oxide Film (nm)

The thickness of the metal oxide film (MgO film) was measured by observation of the Si-based particles using a scanning electron microscope (SEM).

2.4 Pore Volume (cc/g)

The pore volume of the Si-based particles in an unpressed state was measured by pore distribution measurement using nitrogen gas adsorption.

### 2.5 Percentage Change in Pellet Thickness (%)

First, 50 mg of the Si-based particles were placed in an alumina cylinder (diameter: 11.28 mm). Using a uniaxial press machine, the Si-based particles were pressed from above and below with pins (material: SKD11). The pressing load was 1 ton/cm². A pellet of the Si-based particles was thus obtained. The thickness of the pellet of the Si-based particles (hereinafter also referred to as “pellet thickness (1 ton/cm²)”) was measured with a micrometer.

Thereafter, using a uniaxial press machine, the pellet of the Si-based particles was similarly pressed from above and below with pins (material: SKD11). The pressing load was 6 ton/cm². Subsequently, the thickness of the resultant pellet of the Si-based particles (hereinafter also referred to as “pellet thickness (6 ton/cm²)”) was measured with a micrometer.

The percentage change in pellet thickness (%) was calculated using Equation (1) below. A high percentage change in pellet thickness (%) quantitatively indicates that the pore volume of the Si-based particles is less likely to decrease. An acceptable percentage change in pellet thickness (%) is more than 70%.

Percentage change in pellet thickness (%)=Pellet thickness (6 ton/cm²)/Pellet thickness (1 ton/cm²) Equation (1)

### 2.6 Battery Performance

As shown below, an evaluation cell was fabricated using the Si-based particles, and the battery performance (%) was determined.

### 2.6.1 Anode

An anode active material (Si-based particles), a sulfide solid electrolyte (15LiBr-10LiI-75 (0.75Li₂S-0.25P₂S₅)), and an organic solvent (diisobutyl ketone) were mixed and stirred with a homogenizer to obtain a mixture. The volume ratio (Si-based particles:sulfide solid electrolyte) was 65:35. An electrically conductive additive (VGCF) and a binder (PVDF) diluted to 5 mass % were added to the mixture, and the resultant mixture was then stirred with a homogenizer. An anode slurry was thus obtained. The volume fraction of the electrically conductive additive in the anode slurry was 5 vol %. The volume fraction of the binder in the anode slurry was 2 vol %. The obtained anode slurry was applied to an anode current collector (nickel foil) using a cast coater and then dried. An anode was thus obtained. The anode includes an anode current collector and an anode active material layer formed on one main surface of the anode current collector.

### 2.6.2 Solid Electrolyte Layer

A sulfide solid electrolyte (15LiBr-10LiI-75(0.75Li₂S-0.25P₂S₅)), a binder (PVDF) diluted to 5 mass %, and a dispersion medium (a mixture of heptane and dibutyl ether) were mixed. A slurry for a solid electrolyte layer was thus obtained. The solid content of the slurry for a solid electrolyte layer was 50 mass %. The slurry for a solid electrolyte layer was applied to a substrate (aluminum foil) and dried. A solid electrolyte layer with the substrate was thus obtained. The solid electrolyte layer with the substrate includes a substrate and a solid electrolyte layer formed on one main surface of the substrate.

### 2.6.3 Cathode

A cathode active material (LiNi_{1/3}Co_{1/3}Mn_{1/3}O₂), a dispersion medium (butyl butyrate), a binder (5 mass % solution of a PVDF-based binder in butyl butyrate), a sulfide solid electrolyte (15LiBr-10LiI-75(0.75Li₂S-0.25P₂S₅)), and an electrically conductive material (VGCF) were mixed. A cathode slurry was thus obtained. The cathode slurry was applied to a cathode current collector (aluminum foil) and dried. A cathode was thus obtained. The cathode includes a cathode current collector and a cathode active material layer formed on one main surface of the cathode current collector.

### 2.6.4 Evaluation Cell

The solid electrolyte layer was laminated onto the cathode such that the solid electrolyte layer was in contact with the cathode active material layer, and pressing was performed. The substrate (aluminum foil) of the solid electrolyte layer was removed, and the anode was laminated such that the solid electrolyte layer was in contact with the anode active material layer. Pressing was then performed. An evaluation cell was thus obtained.

### 2.6.5 Measurement

The evaluation cell was charged in constant current mode at a current corresponding to a 10-hour rate (0.1 C) until the voltage reached 4.55 V. After the voltage reached 4.55 V, the evaluation cell was charged in constant voltage mode. After the transition to the constant voltage mode, the charging was terminated when the charging current decreased to a current corresponding to 0.01 C.

The evaluation cell was discharged in constant current mode at a current corresponding to 0.1 C. When the voltage reached 3.0 V, the discharging was terminated. The initial charge-discharge efficiency was calculated by dividing the discharge capacity by the charge capacity. The relative value of the initial charge-discharge efficiency, with the initial charge-discharge efficiency of Comparative Example 1 set to 100%, was defined as “battery performance (%).” A high battery performance (%) indicates a larger cell capacity and better battery performance.

TABLE 1

| | | | Si-Based Particles | | | | Evaluation | |
|---|---|---|---|---|---|---|---|---|
| | Coating Step | | | | | Pre- | | Percentage |
| | Coating | | Metal Oxide Film | | | Pressing | | Change in |
| | Step | Firing | | Mg | Film | Pore | Battery | Pellet |
| | Performed | Temperature | Type | Content | Thickness | Volume | Performance | Thickness |
| | — | ° C. | — | (mass %) | nm | cc/g | % | % |
| Example 1 | Yes | 750 | MgO | 24 | 8 | 0.82 | 105 | 84 |
| Example 2 | Yes | 650 | MgO | 16 | 3 | 0.82 | 106 | 77 |
| Comparative | No | — | — | 0.5 | 0 | 0.84 | 100 | 70 |
| Example 1 | | | | | | | | |

In Table 1, “pre-pressing pore volume” refers to the pore volume of the Si-based particles in an unpressed state.

The anode active materials of Examples 1 and 2 included Si-based particles. The Si-based particles included a porous Si particle, and a metal oxide film formed on the surface of the porous Si particle. The metal oxide film contained an Mg element. Therefore, the percentage change in pellet thickness was higher than 70%. As a result, it was found that the anode active materials of Examples 1 and 2 were “anode active materials that are less likely to undergo a decrease in pore volume.”

What is claimed is:

1. An anode active material comprising a plurality of Si-based particles, wherein:
the Si-based particles include a porous Si particle and a metal oxide film that is present on at least a part of a surface of the porous Si particle; and
the metal oxide film contains at least one of an Mg element and an Al element.

2. The anode active material according to claim 1, wherein the metal oxide film is made of MgO.

3. The anode active material according to claim 1, wherein the metal oxide film has a thickness of 3 nm to 8 nm.

4. A solid-state battery comprising:
a cathode;
an anode; and
a solid electrolyte layer disposed between the cathode and the anode, wherein:
the anode includes an anode active material layer; and
the anode active material layer contains the anode active material according to claim 1.

5. A method for manufacturing an anode active material, the method comprising:
preparing a plurality of porous Si particles; and
depositing a metal silicide onto the porous Si particles by physical vapor deposition in a non-oxidizing atmosphere to form a metal oxide film on at least a part of a surface of the porous Si particles, wherein
the metal silicide contains at least one of an Mg element and an Al element.
